(19) United States
(12) Patent Application Publication
(10) Pub. No.: US 2026/0282599 A1
(43) Pub. Date: Sep. 17, 2026

(54) SEMICONDUCTOR OPTICAL DEVICE, SEMICONDUCTOR OPTICAL INTEGRATED DEVICE, AND SEMICONDUCTOR OPTICAL APPARATUS

(71) Applicant: Lumentum Operations LLC, San Jose, CA (US)

(72) Inventors: Shuhei OHNO, Sagamihara (JP); Takanori SUZUKI, Tokyo (JP); Ryosuke HATAI, Sagamihara (JP)

(21) Appl. No.: 19/284,868

(22) Filed: Jul. 30, 2025

(30) Foreign Application Priority Data
Mar. 11, 2025 (JP) 2025038351
May 28, 2025 (JP) 2025088953

(51) Int. Cl. H10F 77/00; H01S 5/026; H10F 30/22; H10F 77/14; H10F 77/20

(52) U.S. Cl. CPC H10F 77/933; H01S 5/0262; H10F 30/22; H10F 77/147; H10F 77/206

(57) ABSTRACT

Provided is a semiconductor optical device that has an excellent characteristic. The semiconductor optical device includes: a semiconductor multilayer including a first conductivity type semiconductor layer, an optical functional layer, and a second conductivity type semiconductor layer; a first electrode including a first connection portion; and a second electrode including a second connection portion. The first electrode is arranged on one side of a mesa structure. The first conductivity type semiconductor layer includes: a mesa portion; and a base portion which is continuous below the mesa portion, extends at least on the one side in a width direction, and is in contact with the first connection portion in a connected portion. The semiconductor optical device includes four or more semiconductor interfaces in a first region on the one side in the width direction of the connected portion of the base portion which is in contact with the first connection portion.

### CROSS-REFERENCE TO RELATED APPLICATION

This Patent Application claims priority to Japan Patent Application No. JP2025-088953, filed on May 28, 2025, and Japan Patent Application No. JP2025-038351, filed on Mar. 11, 2025. The disclosure of the prior Application is considered part of and is incorporated by reference into this Patent Application.

### TECHNICAL FIELD

The present disclosure relates generally to a semiconductor optical device, a semiconductor optical integrated device, and a semiconductor optical apparatus.

### BACKGROUND

A semiconductor optical device used in optical communication can include an optical functional layer at which light emission, absorption, or the like is performed, and two electrodes for inputting electric signals to the optical functional layer. For example, a structure can include two electrodes arranged on a same surface of a semiconductor substrate.

### SUMMARY

An electrode is often required to transmit an electric signal, which is input from an external power source, to an optical functional layer. Further, for connection to the external power source, the electrode includes a portion having a certain size. This portion is called a pad electrode, for example. The pad electrode can generate a parasitic capacitance. An increased parasitic capacitance can cause a decrease in a frequency characteristic when a semiconductor optical device is operated at high frequency.

Some implementations described herein provide a semiconductor optical device that has an excellent characteristic.

In some implementations, a semiconductor optical device includes: a semiconductor multilayer including a first conductivity type semiconductor layer, an optical functional layer, and a second conductivity type semiconductor layer which are grown in the stated order in a stacking direction on a substrate; a first electrode including a first connection portion connected to the first conductivity type semiconductor layer; and a second electrode including a second connection portion connected to the second conductivity type semiconductor layer. A mesa portion of the first conductivity type semiconductor layer, the optical functional layer, and the second conductivity type semiconductor layer form a mesa structure extending in an extending direction. The first electrode is arranged on one side of the mesa structure in a width direction perpendicular to the stacking direction and the extending direction. The first conductivity type semiconductor layer includes: the mesa portion; and a base portion which is continuous below the mesa portion, extends at least on the one side in the width direction, and is in contact with the first connection portion in a connected portion. The semiconductor optical device includes four or more semiconductor interfaces in a first region on the one side in the width direction of the connected portion of the base portion which is in contact with the first connection portion.

### BRIEF DESCRIPTION OF THE DRAWINGS

FIG. 1 is a top view of a semiconductor optical device according to a first example implementation of the present invention.

FIG. 2 is a cross-sectional view taken along the line II-II of the semiconductor optical device illustrated in FIG. 1.

FIG. 3 is a top view for illustrating a cross section taken along the line A-A of the semiconductor optical device illustrated in FIG. 2.

FIG. 4 is a top view for illustrating a cross section taken along the line A-A in a modification example of the first example implementation.

FIG. 5 is a top view for illustrating a cross section taken along the line A-A of a semiconductor optical device according to a second example implementation of the present invention.

FIG. 6 is a cross-sectional view taken along the line VI-VI of the semiconductor optical device illustrated in FIG. 5.

FIG. 7 is a top view for illustrating a cross section taken along the line A-A of a semiconductor optical device according to a third example implementation of the present invention.

FIG. 8 is a top view for illustrating a cross section taken along the line A-A of a semiconductor optical device according to a fourth example implementation of the present invention.

FIG. 9 is a top view for illustrating a cross section taken along the line A-A of a semiconductor optical device according to a fifth example implementation of the present invention.

FIG. 10 is a cross-sectional view taken along the line X-X of the semiconductor optical device illustrated in FIG. 9.

FIG. 11 is a top view of a semiconductor optical device according to a sixth example implementation of the present invention.

FIG. 12 is a cross-sectional view taken along the line XII-XII of the semiconductor optical device illustrated in FIG. 11.

FIG. 13 is a cross-sectional view taken along the line B-B of the semiconductor optical device illustrated in FIG. 11.

FIG. 14 is a cross-sectional view taken along the line C-C of the semiconductor optical device illustrated in FIG. 11.

FIG. 15 is a top view for illustrating a cross section taken along the line A-A of the semiconductor optical device illustrated in FIG. 12.

FIG. 16 is a top view of a semiconductor optical device according to a seventh example implementation of the present invention.

FIG. 17 is a top view of a semiconductor optical integrated device according to an eighth example implementation of the present invention.

FIG. 18 is a cross-sectional view taken along the line XVIII-XVIII of the semiconductor optical integrated device illustrated in FIG. 17.

FIG. 19 is a top view of a semiconductor optical device according to a ninth example implementation of the present invention.

FIG. 20 is a cross-sectional view taken along the line B-B of the semiconductor optical device illustrated in FIG. 19.

FIG. 21 is a top view of a semiconductor optical apparatus according to a tenth example implementation of the present invention.

### DETAILED DESCRIPTION

A specific and detailed description is given below on example implementations of the present invention with reference to the drawings. Members denoted by the same reference symbol throughout the drawings have the same or an equivalent function, and a repetitive description on the members is omitted. Note that sizes of graphics are not always to scale.

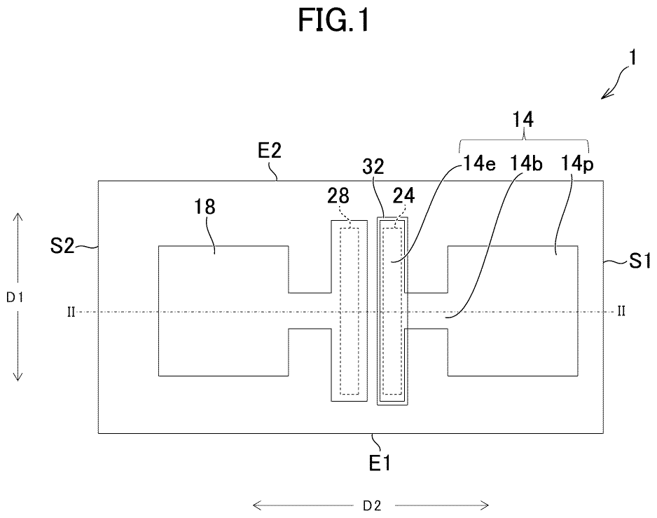

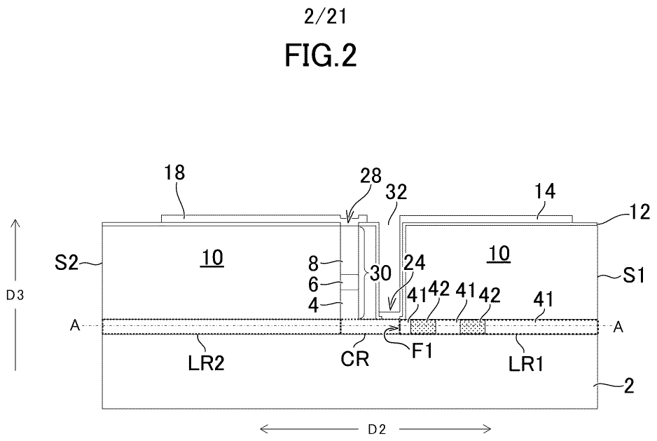

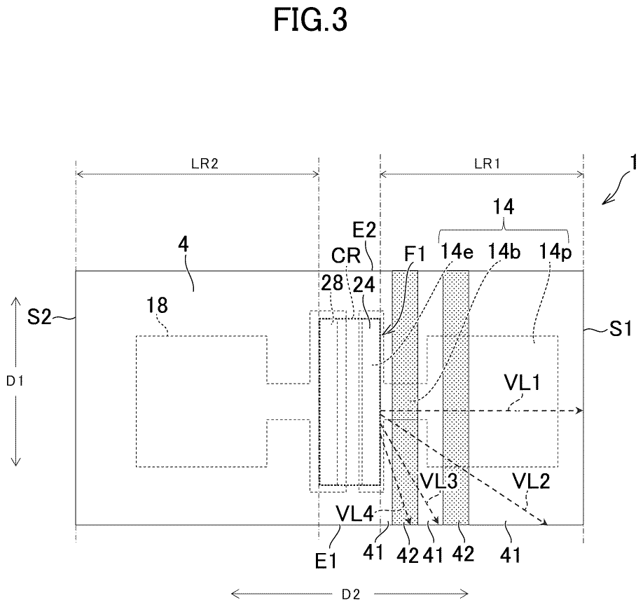

FIG. 1 is a top view of a semiconductor optical device according to a first example implementation of the present invention. FIG. 2 is a cross-sectional view for schematically illustrating a cross section taken along the line II-II of FIG. 1. FIG. 3 is a top view for schematically illustrating a cross section taken along the line A-A of FIG. 2.

The semiconductor optical device 1 may include a semiconductor multilayer including a first conductivity type semiconductor layer 4, an optical functional layer 6, and a second conductivity type semiconductor layer 8 which are grown in the stated order on a substrate 2 which may be a semi-insulating semiconductor. In this case, the first conductivity type is an n-type, and the second conductivity type is a p-type, but the types may be reversed. A mesa portion of the first conductivity type semiconductor layer 4, the optical functional layer 6, and the second conductivity type semiconductor layer 8 include a mesa structure 30 extending in an extending direction D1. The extending direction D1 may be an optical axis direction. A buried layer 10 may be arranged on each of both side surfaces of the mesa structure 30 in a width direction D2 perpendicular to the extending direction D1. The semiconductor optical device 1 may include, on its upper surface, a first electrode 14 and a second electrode 18. The two electrodes may be metal layers. The semiconductor optical device 1 may include an insulating film 12. A normal direction to the substrate 2 is referred to as “stacking direction D3.” The following description is given assuming the direction of the stacking direction D3 to be an up-down direction.

In this case, the semiconductor optical device 1 may be an electro-absorption modulator. The optical functional layer 6 may be a layer for absorbing light in accordance with a voltage applied between the first electrode 14 and the second electrode 18. The optical functional layer 6 may include a plurality of layers. For example, the optical functional layer 6 may include a multiple quantum well (MQW) layer and optical confinement layers arranged above and below the multiple quantum well (MQW) layer. The buried layer 10 is, for example, a semi-insulating semiconductor layer.

The semiconductor optical device 1 may have a first facet E1 and a second facet E2 in the extending direction in which the mesa structure 30 extends. Light of an external light source (not shown) may be input from the first facet E1, and may be output as a modulated optical signal from the second facet E2. The input facet and the output facet may be reversed. Further, a side surface on a side in the width direction D2 on which the first electrode 14 is arranged is referred to as “first side surface S1,” and an opposite side is referred to as “second side surface S2.”

The first conductivity type semiconductor layer 4 at least may include a mesa portion which is included in the mesa structure 30, and a base portion which may be continuous below the mesa portion, extends at least on one side in the width direction, and may be in contact with a first connection portion in a connected portion. The base portion may include the first conductivity type semiconductor layer 4 in a first region LR1, the first conductivity type semiconductor layer 4 in a second region LR2, and a conductive portion CR, each of which are described herein. The first conductivity type semiconductor layer 4 may include a plurality of layers in the stacking direction D3. Another layer may be included between the first conductivity type semiconductor layer 4 and the substrate 2.

The buried layer 10 may have a recessed portion 32, and the first conductivity type semiconductor layer 4 may be arranged at the bottom of the recessed portion 32. The insulating film 12 may be arranged on side surfaces and a part of a bottom surface of the recessed portion 32, but the insulating film 12 is not arranged on another part of the bottom surface of the recessed portion. In the region of the bottom surface of the recessed portion 32 in which the insulating film 12 is not arranged, the first electrode 14 may be electrically and physically connected to the first conductivity type semiconductor layer 4. A portion of the first electrode 14 in which the first electrode 14 and the first conductivity type semiconductor layer 4 are connected to each other is hereinafter referred to as “first connection portion 24.” For the sake of description, in FIG. 1, the first connection portion 24 is indicated by the dotted line.

The first electrode 14 may include a first conducting electrode 14e arranged on the first connection portion 24, a first pad electrode 14p arranged above the buried layer 10, and a first bridge electrode 14b between the first conducting electrode 14e and the first pad electrode 14p. The first pad electrode 14p may be connected to external electric wiring (not shown). The first bridge electrode 14b may be narrower than the first conducting electrode 14e and the first pad electrode 14p in the extending direction D1.

The second conductivity type semiconductor layer 8 may include a plurality of layers. For example, the second conductivity type semiconductor layer 8 may have a structure including a cladding layer and a contact layer arranged above the cladding layer. The insulating film 12 is not arranged at least in a part of an upper surface of the mesa structure 30. In a region of the upper surface of the mesa structure 30 in which the insulating film 12 is not arranged, the second electrode 18 may be electrically and physically connected to the second conductivity type semiconductor layer 8. A portion in which the second electrode 18 and the second conductivity type semiconductor layer 8 are connected to each other is hereinafter referred to as “second connection portion 28.” In this case, in the width direction D2, the width of the second connection portion 28 and the width of the mesa structure 30 may be the same, but the present invention is not limited thereto. For the sake of description, in FIG. 1, the second connection portion 28 is indicated by the dotted line.

A portion which is included in the base portion and consists of a lower portion of the mesa structure and the connected portion is hereinafter referred to as “conductive portion CR.” In other words, the conductive portion CR may include the connected portion overlapping the first connection portion 24 in the stacking direction D3, and a portion overlapping the second connection portion 28 (portion immediately below the mesa structure). Further, the conductive portion CR may include a portion between the portion immediately below the mesa structure and the connected portion. In the first example implementation, positions of both ends in the extending direction D1 of the first connection portion 24 and the second connection portion 28 coincide when viewed from the top, but are shifted from each other in the width direction D2. Therefore, the conductive portion CR has a quadrangular shape when viewed from the top. Further, an upper boundary in the stacking direction D3 of the conductive portion CR is an interface with the mesa structure 30 (that is, an upper surface of the base portion). Still further, a lower interface of the conductive portion CR is an upper surface of the substrate 2. In the first embodiment, the conductive portion CR has a substantially rectangular parallelepiped shape. The shape of the conductive portion CR varies depending on arrangements of the first connection portion 24 and the second connection portion 28. A region on the one side (the first side surface S1 side) in the width direction of the connected portion of the base portion which is in contact with the first connection portion is referred to as “first region LR1.” In other words, the first region LR1 is arranged continuously with the conductive portion CR, and is a region between the conductive portion CR and the first side surface S1. Similarly, a region on the other side (the second side surface S2 side) in the width direction of the portion immediately below the mesa structure of the base portion is referred to as “second region LR2.” In other words, the second region LR2 is arranged continuously with the conductive portion CR, and is a region between the conductive portion CR and the second side surface S2. Further, an upper boundary in the stacking direction D3 of the first region LR1 and the second region LR2 is the upper surface of the base portion, and a lower boundary in the stacking direction D3 is the upper surface of the substrate 2.

The first conductivity type semiconductor layer 4 may be arranged in the second region LR2. The first region LR1, on the other hand, may include portions formed of at least two different semiconductors (first high-resistance portion 41 and second high-resistance portion 42). In the first example implementation, a plurality of high-resistance portions each of which is one of the first high-resistance portion 41 or the second high-resistance portion 42 are alternatingly arranged in the width direction D2. As used herein, the terms “the first high-resistance portion 41” and “the second high-resistance portion 42” do not necessarily mean that those portions themselves have high resistance, and are simply terms for designating elements forming the first region LR1. The first high-resistance portion 41 and the second high-resistance portion 42 are different semiconductors. As used herein, the phrase “the first high-resistance portion 41 and the second high-resistance portion 42 are “different” indicates that the first high-resistance portion 41 and the second high-resistance portion 42 are formed of different semiconductors. The term “different semiconductors” indicates semiconductors that are different from each other at least in any one of dopant, material that serves as a base, or carrier concentration. For example, when the material that serves as a base is InP, an undoped InP portion, an n-type InP portion, a p-type InP portion, and a semi-insulating InP portion are semiconductors different from one another. The undoped semiconductor portion is a semiconductor in which a material that serves as a base is not intentionally doped with any dopant. The n-type InP portion is InP doped with, for example, Si. Similarly, the p-type InP portion is InP doped with Zn, and the semi-insulating InP portion is InP doped with Fe. Those dopants are merely an example, and other dopants may be used. Each of the semiconductors may be doped with a plurality of dopants. For example, the n-type InP portion doped with Si may be doped with Zn until the p-type conductivity is acquired, to thereby form a p-type InP portion. In this case, the n-type InP portion doped with Si alone and the p-type InP portion doped with Si and Zn both are semiconductors different from each other. An example of the case in which different materials are used as bases is a case in which the first high-resistance portion 41 is InP and the second high-resistance portion 42 is not InP. A case in which the first high-resistance portion 41 is InP and the second high-resistance portion 42 is InGaAsP or the like is given as an example. When different materials are used as bases, the first high-resistance portion 41 and the second high-resistance portion 42 may be doped with the same dopant or different dopants. The case in which different carrier concentrations are used is a case in which the carrier concentration of the first high-resistance portion 41 and the carrier concentration of the second high-resistance portion 42 differ from each other. The carrier concentrations are desired to differ from each other by one digit or more. It goes without saying that the different semiconductors differ from each other in, in addition to carrier concentration, dopant and material that serves as a base.

In this case, the first high-resistance portion 41 may be a part of the base portion of the first conductivity type semiconductor layer 4, and may be an n-type InP layer, for example. The second high-resistance portion 42 may be formed of a semiconductor different from that of the first high-resistance portion 41, and may be a p-type InP layer, for example. FIG. 3 is a top view of a cross section taken along the line A-A. For the sake of description, the first connection portion 24, the second connection portion 28, the first electrode 14, and the second electrode 18 are indicated by the dotted lines. In this case, the second high-resistance portion 42 has a rectangular shape reaching from the first facet E1 to the second facet E2 in the extending direction D1 when viewed from the top.

When a high-frequency electric signal is applied to the first electrode 14, the electric signal is transmitted via the first connection portion 24 to the conductive portion CR formed of the first conductivity type semiconductor layer 4, and is finally applied to the optical functional layer 6. Here, as a comparison, a structure in which the second high-resistance portions 42 are not arranged in the first region LR1 is assumed. That is, a structure in which the first region LR1 is entirely formed of the first conductivity type semiconductor layer 4 (that is, the first high-resistance portion 41) is assumed. This structure can be considered to be a structure in which an electrical insulator (the insulating film 12 and the buried layer 10) is interposed between a part of the first bridge electrode 14b or the first pad electrode 14p and the first conductivity type semiconductor layer 4. An electric field applied to the conductive portion CR not only moves to the optical functional layer 6, but also spreads into the first region LR1. Therefore, a capacitance component is caused by the first electrode 14 to hinder high-speed operation. However, in the first example implementation, with two different high-resistance portions being arranged in the first region LR1, the spread of the electric field in the first region LR1 is suppressed and an increase in capacitance is reduced to achieve the high-speed operation. In the first region LR1, different high-resistance portions are alternatingly arranged in the width direction D2 in cross-sectional view. A semiconductor interface is formed between the different high-resistance portions. For example, in the first example implementation, the first high-resistance portion 41 is an n-type layer and the second high-resistance portion 42 is a p-type layer, and hence a plurality of pn interfaces are formed in the first region LR1. Energy barriers of the pn interfaces hinder a flow of carriers. In other words, the spread of the electric field can be reduced.

In the first region LR1, a plane located on the width direction side (the first side surface S1 side) of the connected portion is hereinafter referred to as “first reference plane F1.” In other words, the first reference plane F1 is an interface between the conductive portion CR and the first region LR1. The first reference plane F1 is an imaginary plane extending from a side on the first side surface S1 side of the first connection portion 24 in the direction of the stacking direction D3. In order to suppress the spread of the electric field, it is preferred that the number of semiconductor interfaces be larger. In order to achieve the effect of the present invention, it is desired that, in the first region LR1, imaginary lines VL extending from any position on the first reference plane F1 in a direction parallel to the surface of the substrate 2 penetrate at least four or more semiconductor interfaces before reaching the first side surface S1. In the first example implementation, an imaginary line VL1 extending to the first side surface S1 penetrates all of four semiconductor interfaces. Further, it is preferred that the imaginary line penetrate the semiconductor interfaces before reaching the first facet E1 or the second facet E2. In the first example implementation, the imaginary line does not necessarily penetrate four semiconductor interfaces. For example, in FIG. 3, an imaginary line VL2 penetrates four semiconductor interfaces, but an imaginary line VL3 and an imaginary line VL4 do not penetrate four semiconductor interfaces. The imaginary lines VL simulate the spread of the electric field, and penetrating the four or more semiconductor interfaces is equivalent to suppressing the spread of the electric field. However, it is not necessarily required for every imaginary line VL (distribution of the spread of the electric field) to penetrate four semiconductor interfaces to achieve the effect of the present invention. In this case, the semiconductor interface the imaginary lines VL penetrate means an interface arranged in the direction of the extending direction D1 or the width direction D2, and does not mean an interface arranged in the direction of the stacking direction D3.

Further, in order to suppress the range of the electric field spreading from the conductive portion CR, it is preferred that an interface of different semiconductor layers be closer to the first reference plane F1. Ideally, the first reference plane F1 and an interface of a second high-resistance portion 42 coincide. However, when the second high-resistance portion 42 is displaced in the width direction D2 to overlap the first connection portion 24 when viewed from the top due to a variation in manufacturing, application of a voltage to the conductive portion CR is undesirably hindered. Therefore, in the first example implementation, the semiconductor interface closest to the conductive portion CR is arranged to be spaced apart from the first reference plane F1. However, when the distance therebetween is too large, the effect of suppressing the spread of the electric field is weakened. Therefore, it is desired that, in the width direction D2, the semiconductor interface closest to the first reference plane F1 be arranged at a position overlapping the first bridge electrode 14b when viewed from the top.

In the first example implementation, the first high-resistance portion 41 is formed of the same semiconductor as that of the first conductivity type semiconductor layer 4, but the present invention is not limited thereto. The first high-resistance portion 41 may be formed of a semiconductor different from that of the first conductivity type semiconductor layer 4. The first high-resistance portion 41 and the second high-resistance portion 42 are not limited to the n-type layer and the p-type layer, respectively, and may be an undoped layer or a semi-insulating layer as described above. For example, also when any one of the first high-resistance portion 41 or the second high-resistance portion 42 is formed of an undoped semiconductor or a semi-insulator, an energy barrier is formed with a conductivity type semiconductor to prevent the flow of carriers and suppress the spread of the electric field. Further, the portion formed of the undoped semiconductor or the semi-insulator has a high electrical resistivity itself, and can suppress the spread of the electric field also in this respect. Therefore, even when only the two materials of the undoped semiconductor and the semi-insulator are arranged in the first region LR1, the effect of the present invention can be achieved.

Further, it is not necessary that two second high-resistance portions 42 be formed of the same semiconductor. For example, in order from the first high-resistance portion 41 adjacent to the first reference plane F1 in the width direction D2 (toward the first side surface S1), a p-type semiconductor (the second high-resistance portion 42), an n-type semiconductor (the first high-resistance portion 41), an undoped semiconductor (the second high-resistance portion 42), and an n-type semiconductor (the first high-resistance portion 41) may be arranged. Further, the different semiconductors are not necessarily required to be formed of the same material that serves as a base, but are desirably formed of the same material from viewpoints of manufacturability and crystallinity.

The second high-resistance portions 42 may be formed by any method. For example, a method may be adopted in which, after the first conductivity type semiconductor layer 4 is formed through epitaxial growth on the substrate 2, a dopant of the second conductivity type is distributed in regions for forming the second high-resistance portions 42, to thereby form two second high-resistance portions 42 in the regions. In the first region LR1, regions in which the second high-resistance portions 42 are not formed remain as the first conductivity type semiconductor layers 4. In the first example implementation, these remaining regions of the first conductivity type semiconductor layer 4 are referred to as “first high-resistance portions 41.” Another method of forming is a method of forming the second high-resistance portions 42 by the epitaxial growth. After the first conductivity type semiconductor layer 4 is formed, the first conductivity type semiconductor layer 4 in the regions for forming the second high-resistance portions 42 is removed. In the regions in which the first conductivity type semiconductor layer 4 is removed, a semiconductor layer different from the first conductivity type semiconductor layer 4 is epitaxially grown to form the second high-resistance portions 42. These are merely one example of the forming method.

It may be further desired that, when viewed in the direction of the extending direction D1, both ends on the extending direction D1 side of the second connection portion 28 be arranged inside both ends on the extending direction D1 side of the first connection portion 24, respectively. In this case, both ends on the extending direction D1 side of the first connection portion 24 and both ends on the extending direction D1 side of the second connection portion 28 are arranged collinearly in the width direction D2. In other words, when viewed from the top, the first connection portion 24 and the second connection portion 28 are arranged at the same position in the extending direction D1, and at displaced positions in the width direction D2. The voltage applied between the first connection portion 24 and the second connection portion 28 acts on the optical functional layer 6. At this time, as the positional displacement between the first connection portion 24 and the second connection portion 28 is smaller, the spread of the electric field applied to the respective connection regions can be better suppressed. This leads to a decrease in capacitance. In the first example implementation, the first connection portion 24 and the second connection portion 28 do not reach the first facet E1 and the second facet E2, but the present invention is not limited thereto.

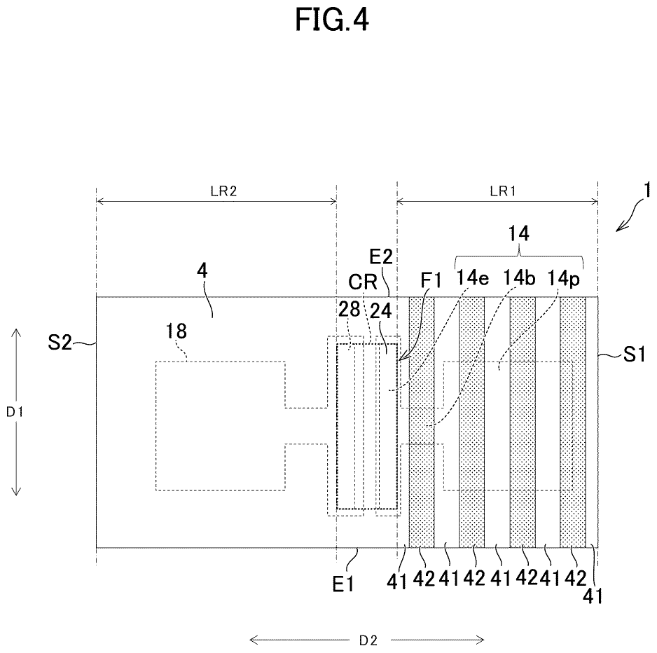

FIG. 4 is a top view for schematically illustrating a cross section taken along the line A-A in a modification example of the semiconductor optical device 1 of the first example implementation, and corresponds to FIG. 3. The difference from the first example implementation resides in the configuration of the first region LR1.

In the modification example of the first example implementation, the first region LR1 has five first high-resistance portions 41 and four second high-resistance portions 42. Therefore, when viewed from the first reference plane F1, the imaginary lines penetrate at most eight semiconductor interfaces. With the arrangement of a large number of semiconductor interfaces, the spread of the electric field is further suppressed, the occurrence of a parasitic capacitance is reduced, and the semiconductor optical device adapted to the high-speed operation can be achieved. In this case, each of a plurality of first high-resistance portions 41 and a plurality of second high-resistance portions 42 has a constant width in the width direction D2, but the present invention is not limited thereto.

As described above, it may be desired that, in the first region LR1, any one of the imaginary lines extending from any position on the first reference plane F1 in the direction parallel to the surface of the substrate 2 penetrate at least four or more semiconductor interfaces. However, in order to further suppress the spread of the electric field, it may be desired that the imaginary line penetrate six or more semiconductor interfaces.

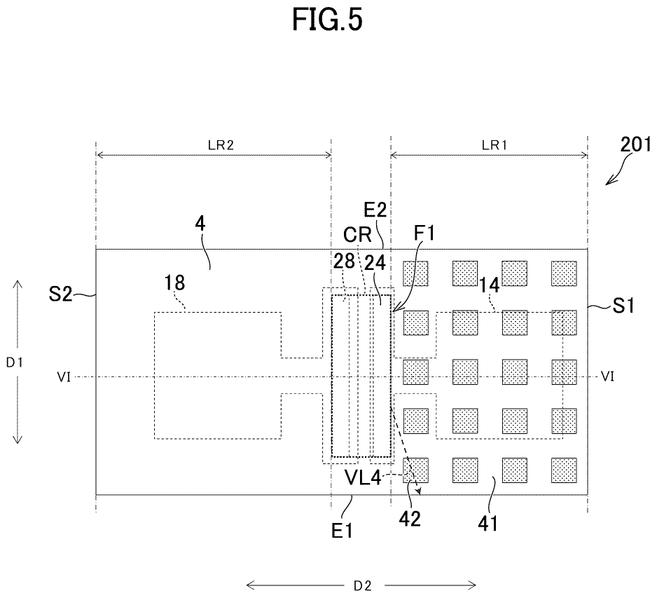

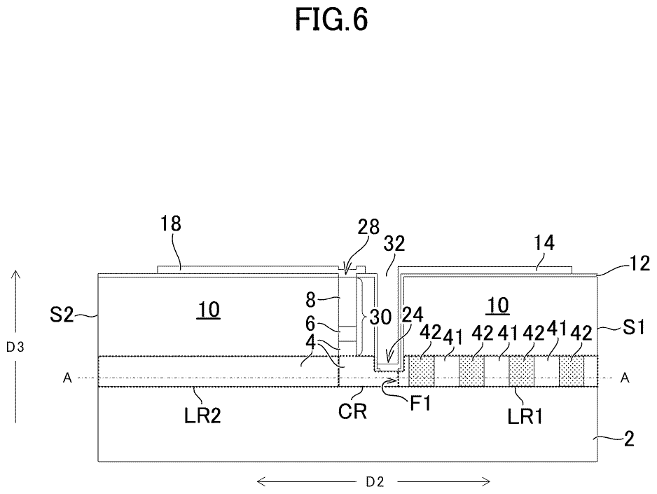

FIG. 5 is a top view of a semiconductor optical device 201 according to a second example implementation of the present invention, and corresponds to a cross-sectional view taken along the line A-A of the first example implementation. FIG. 6 is a cross-sectional view of the semiconductor optical device 201, and corresponds to FIG. 2. The difference from the first example implementation resides in the configuration of the first region LR1.

In the second example implementation, the conductive portion CR is thicker in the stacking direction D3 than in the first example implementation. The recessed portion 32 has a depth reaching not only to the buried layer 10 but also to the middle of the base portion of the first conductivity type semiconductor layer 4. Therefore, the conductive portion CR has a cross section of a three-dimensional shape of a letter L instead of the rectangular parallelepiped shape. Similarly, the first region LR1 has a shape having a dent in the upper left corner as illustrated in FIG. 6 instead of a simple rectangular parallelepiped shape. The second region LR2 has a rectangular parallelepiped shape.

In the first region LR1, the second high-resistance portions 42 are arranged in islands in the first high-resistance portion 41. In the first example implementation, the second high-resistance portion 42 is arranged without interruption in the extending direction D1. Therefore, the electric field may spread in the extending direction D1 in the second high-resistance portion 42. In the second example implementation, the spread of the electric field is reduced by arranging the second high-resistance portions 42 in islands. For example, assuming the imaginary line VL4 described in the first example implementation, the imaginary line VL4 penetrates two semiconductor interfaces. In the first example implementation, on the other hand, the imaginary line VL1 penetrates one semiconductor interface. Therefore, as compared to the first example implementation, in the second example implementation, the spread of the electric field in the direction of the extending direction D1 can be further reduced.

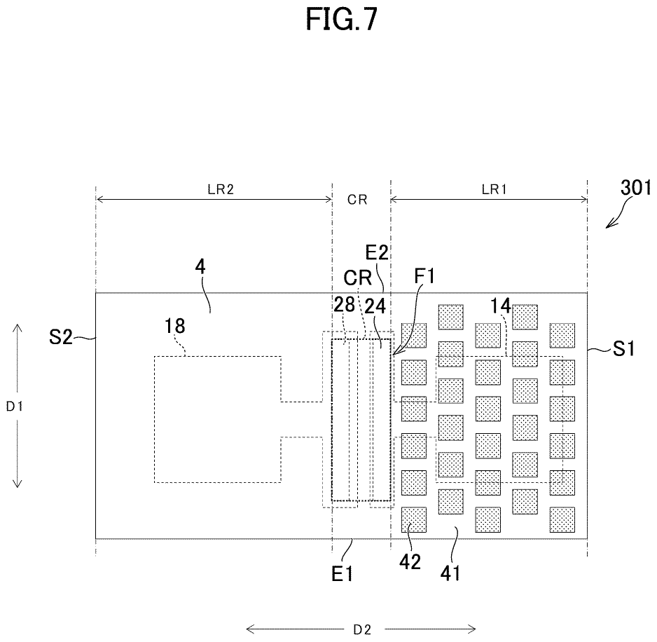

FIG. 7 is a top view of a semiconductor optical device 301 according to a third example implementation of the present invention, and corresponds to a cross-sectional view taken along the line A-A of the first example implementation. The difference from the first example implementation and the second example implementation resides in the configuration of the first region LR1.

As described in the second example implementation, with the arrangement of the second high-resistance portions 42 in islands, the spread of the electric field in the direction of the extending direction D1 can be suppressed. However, when ends on the extending direction D1 side of the plurality of second high-resistance portions 42 coincide, the imaginary line VL heading to the first side surface S1 may not penetrate semiconductor interfaces. In order to prevent this situation, in the third example implementation, the second high-resistance portions 42 are arranged in islands in a staggered manner. With this arrangement, the imaginary lines VL heading to the first side surface S1 always penetrate semiconductor interfaces. Further, with a size of the second high-resistance portions 42 being set larger than an interval with the adjacent second high-resistance portions 42, the imaginary lines VL in an orientation heading the first facet E1 or the second facet E also penetrate the semiconductor interfaces except for some of the imaginary lines VL. That is, only the imaginary lines VL heading from the first reference plane F1 to the first facet E1 or the second facet E2 without penetrating the semiconductor interface closest to the first reference plane F1 do not penetrate the semiconductor interfaces. This is because, as described above, the first reference plane F1 and the second high-resistance portions 42 cannot be arranged adjacent to each other from the viewpoint of the variation in manufacturing. However, many of the imaginary lines VL passing through the region overlapping the first pad electrode 14p, which becomes the cause of occurrence of the capacitance component in particular, penetrate four or more semiconductor interfaces, and hence the spread of the electric field is suppressed to prevent the occurrence of the capacitance.

The shape of each second high-resistance portion 42 when viewed from the top is not limited to the quadrangle, and may be any one of a polygon, a circle, or a shape obtained by combining straight and curved lines.

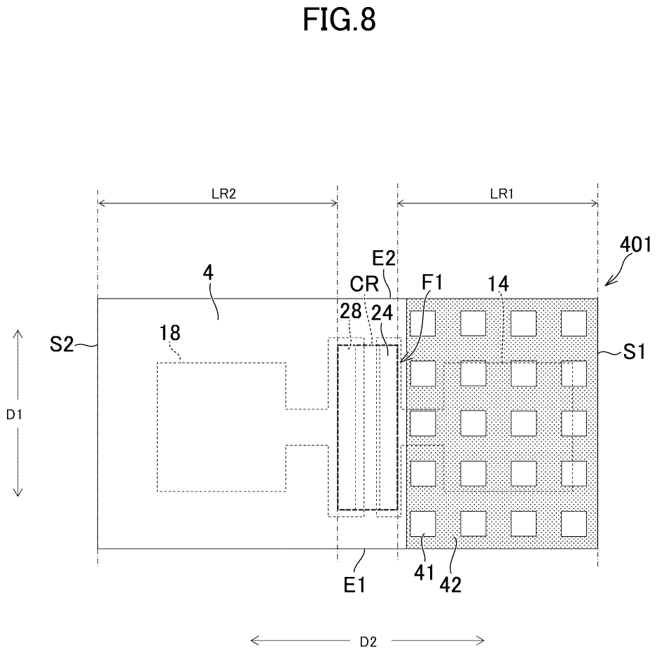

FIG. 8 is a top view of a semiconductor optical device 401 according to a fourth example implementation of the present invention, and corresponds to a cross-sectional view taken along the line A-A of the first example implementation. The difference from the first example implementation resides in the configuration of the first region LR1.

In the fourth example implementation, the first high-resistance portions 41 are arranged in islands in the second high-resistance portion 42. In this case, the first high-resistance portions 41 are parts of the first conductivity type semiconductor layer 4, and the second high-resistance portion 42 is formed of a semiconductor different from that of the first conductivity type semiconductor layer 4. Also with this structure, a plurality of semiconductor interfaces can be formed, and the spread of the electric field can be suppressed.

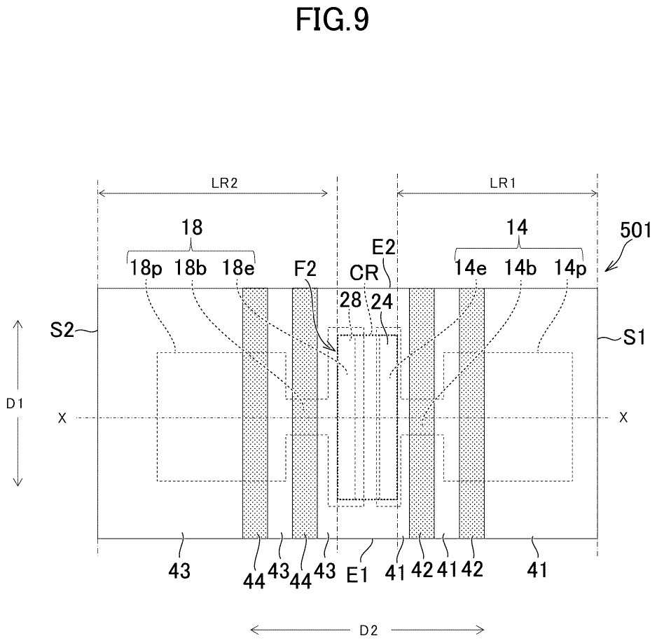

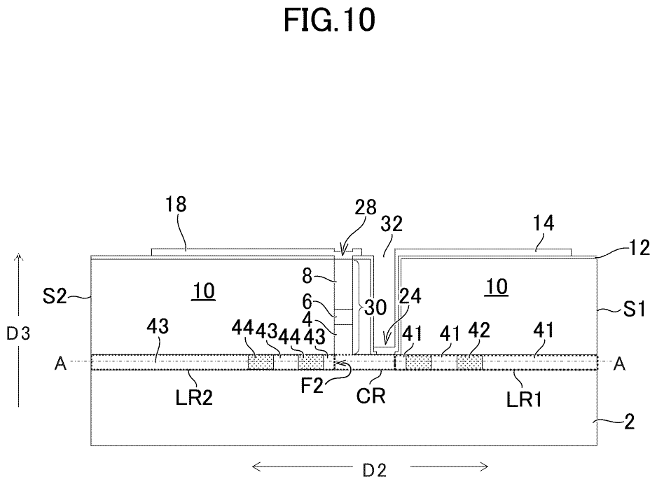

FIG. 9 is a top view of a semiconductor optical device 501 according to a fifth example implementation of the present invention, and corresponds to a cross-sectional view taken along the line A-A of the first example implementation. FIG. 10 is a cross-sectional view for schematically illustrating a cross section (a cross section corresponding to a position of the line X-X of FIG. 9) of the semiconductor optical device 501 according to the fifth example implementation. The difference from the first example implementation resides in that the second region LR2 includes a plurality of semiconductor interfaces.

The second region LR2 includes third high-resistance portions 43 and fourth high-resistance portions 44. The third high-resistance portion 43 is formed of one semiconductor, but the present invention is not limited thereto. The fourth high-resistance portion 44 is formed of a semiconductor different from that of the third high-resistance portion 43. In this case, the third high-resistance portion 43 may be the same as, or different from, the semiconductor of each of the first high-resistance portion 41 and the second high-resistance portion 42. Similarly, the fourth high-resistance portion 44 may be the same as, or different from, the semiconductor of each of the first high-resistance portion 41 and the second high-resistance portion 42. It should be noted that the first high-resistance portion 41 and the second high-resistance portion 42 are semiconductors different from each other, and the third high-resistance portion 43 and the fourth high-resistance portion 44 are semiconductors different from each other.

The second electrode 18 includes a second conducting electrode 18e arranged on the second connection portion 28, a second pad electrode 18p arranged above the buried layer 10, and a second bridge electrode 18b between the second conducting electrode 18e and the second pad electrode 18p. The second pad electrode 18p is connected to external electric wiring (not shown).

In the semiconductor optical device 1 according to the first example implementation, only the first conductivity type semiconductor layer 4 is arranged in the second region LR2. Therefore, an electric field applied to the conductive portion CR spreads also to the second region LR2. On the top of the second region LR2, the second electrode 18 is arranged with an interposition of the electrical insulator (the buried layer 10 and the insulating film 12). Therefore, a capacitance caused by the second electrode 18 occurs. In the fifth example implementation, as in the first region LR1, a plurality of semiconductor interfaces are formed in the second region LR2, and hence the spread of the electric field is suppressed to suppress the occurrence of the capacitance caused by the second electrode 18.

In this case, in the second region LR2, a plane located on the width direction side (the second side surface S2 side) of the connected portion is referred to as “second reference plane F2.” In other words, the second reference plane F2 is an interface between the conductive portion CR and the second region LR2. In order to suppress the spread of the electric field, it is preferred that the number of semiconductor interfaces be larger. In order to achieve the effect of the present invention, it is desired that, in the second region LR2, imaginary lines VL extending from any position on the second reference plane F2 in the direction parallel to the surface of the substrate 2 penetrate at least four or more semiconductor interfaces before reaching the second side surface S2.

Further, in order to suppress the range of the electric field spreading from the conductive portion CR, it is preferred that an interface of different semiconductors be closer to the second reference plane F2. Ideally, the second reference plane F and an interface of a fourth high-resistance portion 44 coincide. However, when the fourth high-resistance portion 44 is displaced in the width direction D2 due to a variation in manufacturing to overlap the mesa structure 30 when viewed from the top, the application of the voltage to the conductive portion CR is undesirably hindered. Therefore, in the fifth example implementation, the semiconductor interface closest to the conductive portion CR is arranged to be spaced apart from the second reference plane F2. However, when the distance therebetween is too large, the effect of suppressing the spread of the electric field is weakened. Therefore, it is desired that, in the width direction D2, the semiconductor interface closest to the second reference plane F2 be arranged at a position overlapping the second bridge electrode 18b when viewed from the top.

To the two high-resistance portions arranged in the second region LR2, the same arrangement as the two high-resistance portions arranged in the first region LR1 described in the other example implementations may be applied. At this time, the structures of the first region LR1 and the second region LR2 may have the same arrangement or may be different from each other.

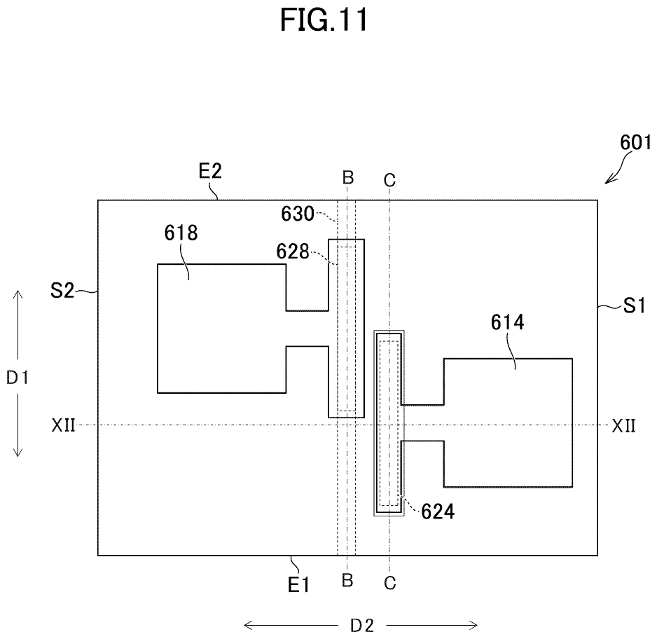

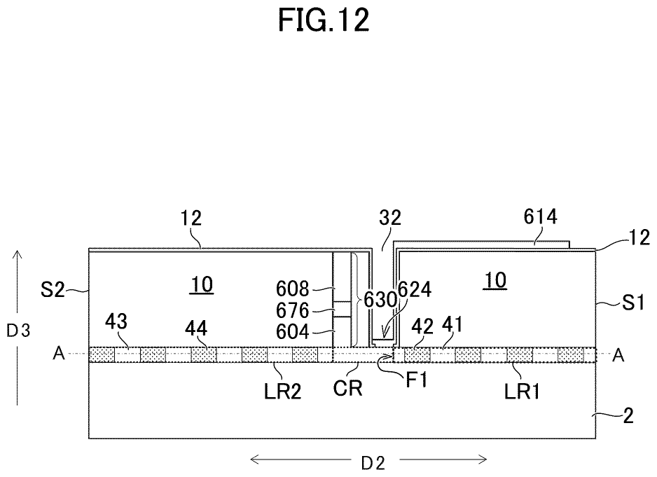

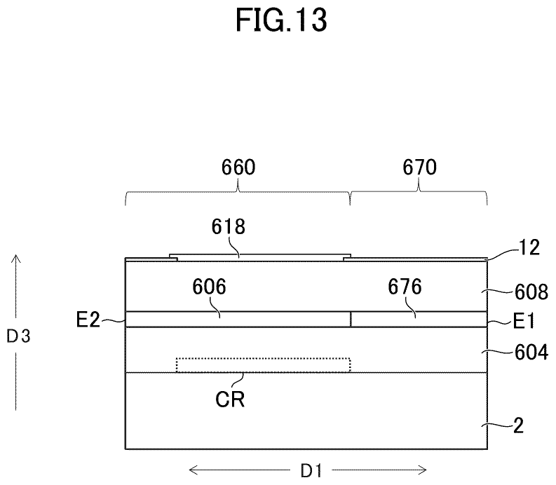

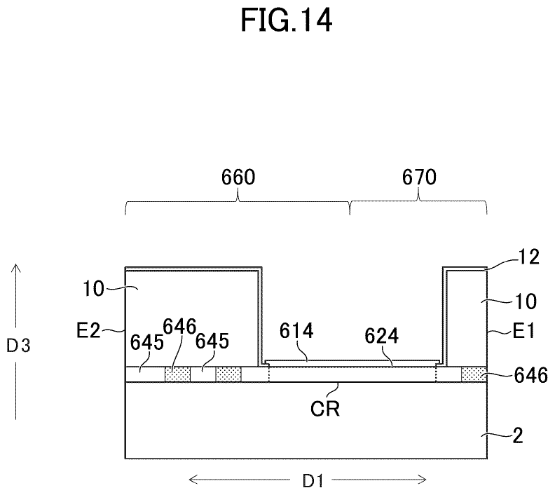

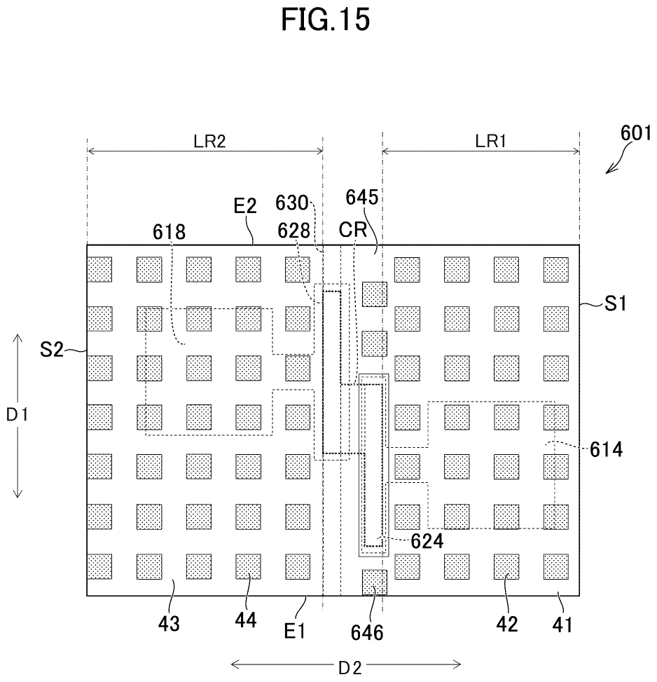

FIG. 11 is a top view of a semiconductor optical device 601 according to a sixth example implementation of the present invention. FIG. 12 is a cross-sectional view for schematically illustrating a cross section taken along the line XII-XII of FIG. 11. FIG. 13 is a cross-sectional view for schematically illustrating a cross section taken along the line B-B of FIG. 11. FIG. 14 is a cross-sectional view for schematically illustrating a cross section taken along the line C-C of FIG. 11. FIG. 15 is a top view for schematically illustrating a cross section taken along the line A-A of FIG. 12.

The semiconductor optical device 601 includes a modulation section 660 and a waveguide section 670. The modulation section 660 has a semiconductor multilayer including, above the substrate 2, a first conductivity type semiconductor layer 604, an optical functional layer 606, and a second conductivity type semiconductor layer 608. The waveguide section 670 has a semiconductor multilayer including, above the substrate 2, the first conductivity type semiconductor layer 604, a waveguide layer 676, and the second conductivity type semiconductor layer 608. The first conductivity type semiconductor layer 604 and the second conductivity type semiconductor layer 608 are structures common to the modulation section 660 and the waveguide section 670. Further, a boundary between the modulation section 660 and the waveguide section 670 is defined by an interface between the optical functional layer 606 and the waveguide layer 676.

The semiconductor optical device 601 has a mesa structure 630. The mesa structure 630 is arranged across the modulation section 660 and the waveguide section 670. The buried layer 10 is arranged on side surfaces on the width direction D2 side of the mesa structure 630. The semiconductor optical device 601 has a first electrode 614 connected to the first conductivity type semiconductor layer 604, and a second electrode 618 connected to the second conductivity type semiconductor layer 608. The first conductivity type semiconductor layer 604 and the first electrode 614 are connected to each other by a first connection portion 624. The first connection portion 624 is arranged across the modulation section 660 and the waveguide section 670. The second conductivity type semiconductor layer 608 and the second electrode 618 are connected by a second connection portion 628, which is an upper surface of the mesa structure 630. The first connection portion 624 and the second connection portion 628 are arranged to be displaced along the extending direction D1.

As in the other example implementations, the semiconductor optical device 601 has the conductive portion CR. The conductive portion CR includes a region overlapping the first connection portion 624 and the second connection portion 628 in the stacking direction D3. Further, the conductive portion CR includes a region therebetween. The term “region therebetween” refers to a region between regions in which the first connection portion 624 and the second connection portion 628 overlap in the width direction D2. Therefore, a shape of the conductive portion CR when viewed from the top is a shape indicated by the dotted line of FIG. 15. As in the other example implementations, in the base portion, a region on the one side (the first side surface S1 side) in the width direction of the connected portion which is in contact with the first connection portion is referred to as “first region LR1.” A region on the other side (the second side surface S2 side) in the width direction of the portion immediately below the mesa structure of the base portion is referred to as “second region LR2.”

The first region LR1 has the first high-resistance portion 41 and the second high-resistance portions 42. The second region LR2 has the third high-resistance portion 43 and the fourth high-resistance portions 44. Their characteristics are similar to those in the other example implementations. In this example, the structure in which the second high-resistance portions 42 and the fourth high-resistance portions 44 are arranged in islands is illustrated, but another structure may be adopted.

The semiconductor optical device 601 has, in a region between the conductive portion CR and each of the first facet E1 and the second facet E2, a fifth high-resistance portion 645 and sixth high-resistance portions 646 which are formed of a semiconductor different from that of the fifth high-resistance portion 645. In this example, in a region overlapping the first connection portion 624 in the extending direction D1, the fifth high-resistance portion 645 and the sixth high-resistance portions 646 are arranged. Characteristics of the two high-resistance portions are the same as those of the other high-resistance portions. In this case, the fifth high-resistance portion 645 is formed of the same semiconductor as a mesa portion of the first conductivity type semiconductor layer 604, and the sixth high-resistance portion 646 is formed of a semiconductor different therefrom. As in the sixth example implementation, with semiconductor interfaces formed between the conductive portion CR and the first facet E1 or the second facet E2, the spread of the electric field can be further suppressed.

In this example, no semiconductor interface is formed in a region overlapping the mesa structure 630 in the stacking direction D3. This is to prevent light propagating mainly through the mesa structure 630 from being affected. Therefore, when higher importance is placed on the effect of reducing the spread of the electric field, that is, the capacitance, the semiconductor interfaces may be formed also in the region overlapping the mesa structure 630.

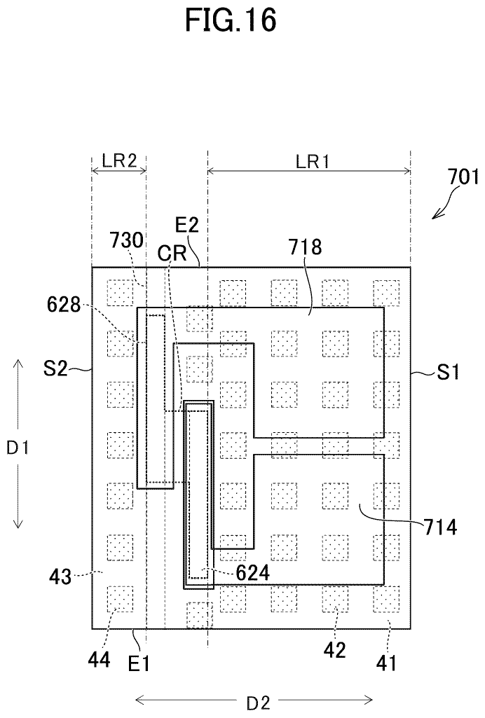

FIG. 16 is a top view of a semiconductor optical device 701 according to a seventh example implementation of the present invention. The seventh example implementation is the same as the sixth example implementation in semiconductor multilayer structure, but is different in position of a mesa structure 730, structure of a first electrode 714, and arrangement of a second electrode 718.

In the seventh example implementation, pad electrodes of the first electrode 714 and the second electrode 718 are both arranged at positions overlapping the first region LR1. Further, the seventh example implementation may be different in connection position between a bridge electrode and a conducting electrode of each electrode. The mesa structure 730 is arranged at a position displaced from the center of the semiconductor optical device 701 in the width direction D2. For description, the first high-resistance portion 41, the second high-resistance portions 42, the third high-resistance portion 43, and the fourth high-resistance portions 44 are illustrated in a transparent manner.

In the seventh example implementation, a plurality of semiconductor interfaces arranged in the first region LR1 can achieve the effect of reducing the capacitances of both the first electrode 714 and the second electrode 718. No semiconductor interface may be formed in the second region LR2.

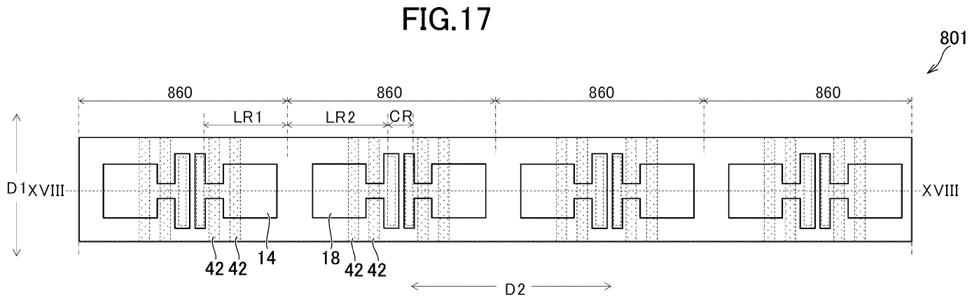

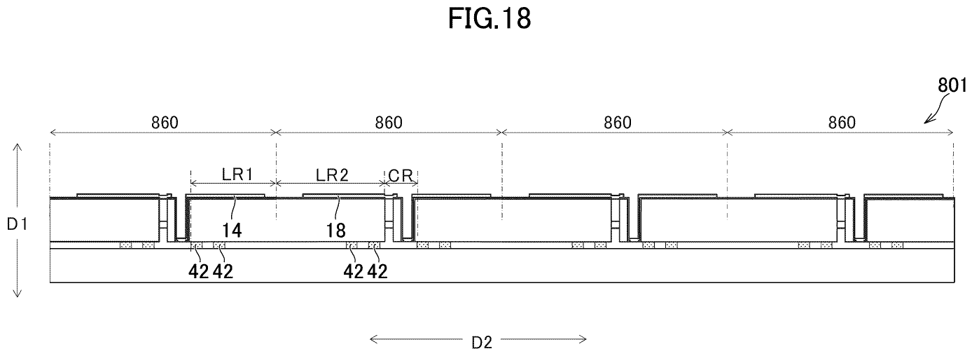

FIG. 17 is a top view of a semiconductor optical integrated device 801 according to an eighth example implementation of the present invention. FIG. 18 is a cross-sectional view for schematically illustrating a cross section taken along the line XVIII-XVIII of FIG. 17.

The semiconductor optical integrated device 801 has a plurality of modulation sections 860. In this example, each modulation section 860 has the same structure as the semiconductor optical device 501 according to the fifth example implementation. The present invention is not limited thereto, and the semiconductor optical device according to any one of the other example implementations may be adopted. In this example, four modulation sections 860 are integrated on the substrate 2. The number of modulation sections 860 is not limited to four, and may be another number.

Each modulation section 860 has a plurality of semiconductor interfaces in the first region LR1 and the second region LR2. FIG. 17 illustrates the second high-resistance portions 42 in a transparent manner for description. As illustrated in FIG. 18, the first region LR1 of the leftmost modulation section 860 and the second region LR2 of the next modulation section 860 are adjacent to each other. The boundary therebetween is not clearly defined, and any position between the first electrode 14 of the leftmost modulation section 860 and the second electrode 18 of the next modulation section becomes the boundary.

When no semiconductor interface is formed in the first region LR1 or the second region LR2, electrical crosstalk occurs between adjacent modulation sections 860 via the first region LR1 and the second region LR2 adjacent thereto, and characteristics as a modulator may deteriorate. In the eighth example implementation, with the plurality of semiconductor interfaces formed as described above, the spread of the electric field is suppressed. Therefore, it is possible to reduce the effect of, for example, the electric field applied to the first electrode 14 of the leftmost modulation section 860 on the conductive portion CR of the next modulation section 860. As described above, with the structure of the present invention, not only the capacitance caused by the electrodes can be reduced, but also in the structure in which the plurality of modulation sections 860 are integrated, the plurality of modulation sections 860 can be prevented from electrically interfering with each other.

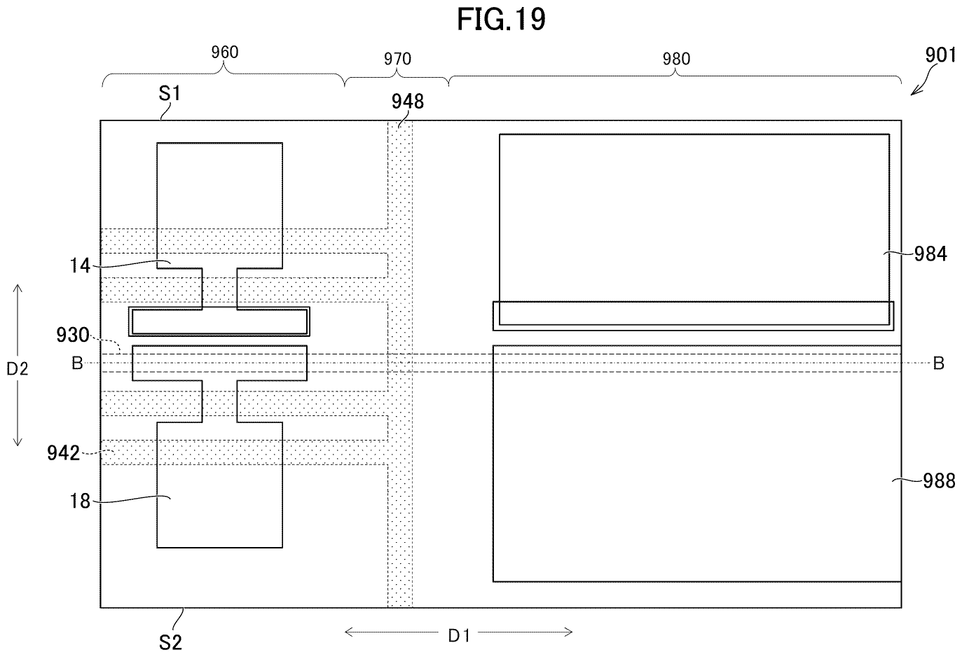

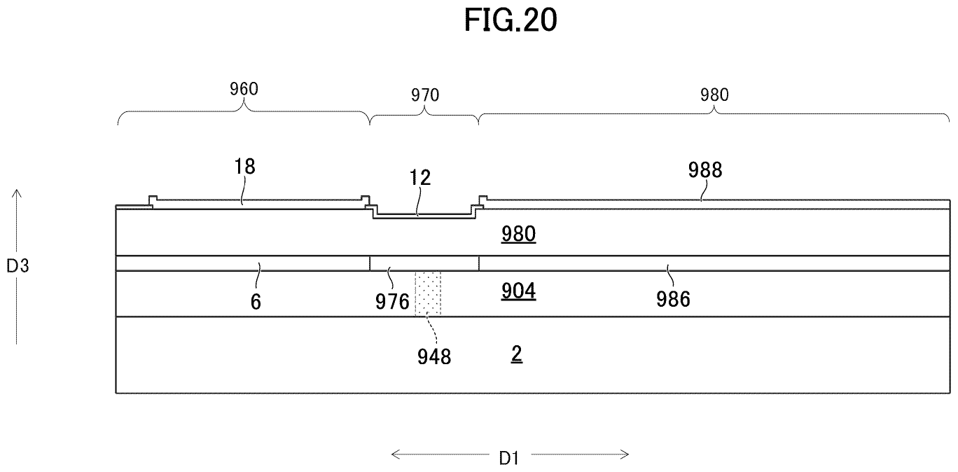

FIG. 19 is a top view of a semiconductor optical device 901 according to a ninth example implementation of the present invention. FIG. 20 is a cross-sectional view for schematically illustrating a cross section taken along the line B-B of FIG. 19. In the semiconductor optical device 901, in addition to any one of the above-mentioned semiconductor optical devices that are modulators, a laser section 980 and a waveguide section 970 are integrated on the substrate 2. A modulation section 960 has the same structure as the semiconductor optical device 501 according to the fifth example implementation. However, the modulation section 960 is not limited thereto, and may be a semiconductor optical device (modulator) according to any one of the other example implementations. A mesa structure 930 is formed across the modulation section 960, the waveguide section 970, and the laser section 980. A buried layer is arranged on each of side surfaces of the mesa structure 930 on the width direction D2 side.

The laser section 980 includes, on the substrate 2, a first conductivity type semiconductor layer 904, an active layer 986, and a second conductivity type semiconductor layer 908. In the buried layer, a recessed portion is formed so as to reach the first conductivity type semiconductor layer 904, and a first laser electrode 984 is in contact with the first conductivity type semiconductor layer 904 in a bottom surface of the recessed portion. Further, a second laser electrode 988 is connected to the second conductivity type semiconductor layer 908 on an upper surface of the mesa structure 930. The laser section 980 emits continuous light in accordance with a voltage applied between the two electrodes (injection of a current).

The waveguide section 970 includes, on the substrate 2, the first conductivity type semiconductor layer 904, a waveguide layer 976, and the second conductivity type semiconductor layer 908. The waveguide section 970 transmits the output light of the laser section 980 to the modulation section 960.

The boundary between the modulation section 960 and the waveguide section 970 is defined as an interface between the optical functional layer 6 and the waveguide layer 976. Similarly, the boundary between the waveguide section 970 and the laser section 980 is defined as an interface between the waveguide layer 976 and the active layer 986.

The first conductivity type semiconductor layer 904 is a layer common to the modulation section 960, the waveguide section 970, and the laser section 980. In the modulation section 960, second high-resistance portions 942 are arranged in the first region LR1 and the second region LR2. Therefore, as in the other example implementations, a plurality of semiconductor interfaces are arranged in the first region LR1 and the second region LR2.

In the waveguide section 970, a waveguide high-resistance portion 948 continuous with the second high-resistance portions 942 is arranged. For description, three high-resistance portions are illustrated in a transparent manner. The waveguide high-resistance portion 948 reaches from the first side surface S1 to the second side surface S2.

Different electric signals are applied to the modulation section 960 and the laser section 980. The electric signals may generate a crosstalk via the first conductivity type semiconductor layer 904 or the second conductivity type semiconductor layer 908. In the ninth example implementation, with the waveguide high-resistance portion 948 being arranged in the waveguide section 970, the semiconductor interfaces are formed to suppress the spread of the electric field. Further, in the stacking direction D3, the second conductivity type semiconductor layer 908 is formed to be thinner and have a high resistance, to thereby suppress the spread of the electric field. Further, with the second high-resistance portions 942 and the waveguide high-resistance portion 948 being continuous with each other, the electric field applied to the modulation section 960 is prevented from spreading over the entire first conductivity type semiconductor layer 904.

In this case, the second high-resistance portions 942 and the waveguide high-resistance portion 948 may be formed of the same semiconductor. Further, as long as the semiconductor is at least different from that of a mesa portion of the first conductivity type semiconductor layer 904, the second high-resistance portions 942 and the waveguide high-resistance portion 948 may be different semiconductors.

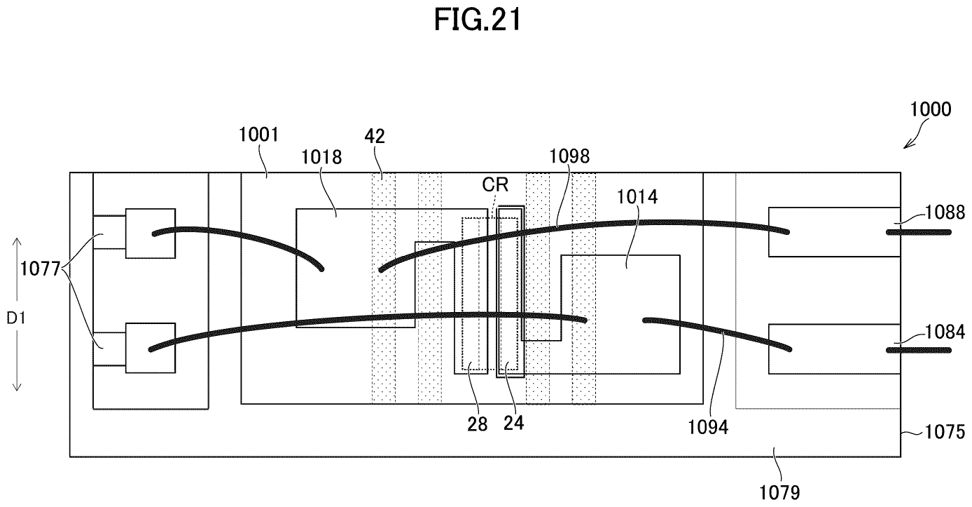

FIG. 21 is a top view of a semiconductor optical apparatus 1000 according to a tenth example implementation of the present invention. The semiconductor optical apparatus 1000 has a structure in which a semiconductor optical device 1001 is mounted on a sub-mount 1075. In this example, the semiconductor optical device 1001 has the same structure as the semiconductor optical device 501 according to the fifth example implementation except for being different in shapes of a first electrode 1014 and a second electrode 1018. The present invention is not limited thereto, and the semiconductor optical device according to any one of the other example implementations may be adopted. For description, the second high-resistance portions 42 are illustrated in a transparent manner.

The sub-mount 1075 has a structure in which a surface of a ceramic substrate is metalized. The sub-mount 1075 includes a first transmission line 1084 and a second transmission line 1088. Electric signals are applied from the outside to the two transmission lines. The sub-mount 1075 includes two matching resistors 1077 and a conductive pattern 1079. The conductive pattern 1079 is connected to a reference potential (ground potential). An electrode for connection to the sub-mount 1075 is formed on a back surface of the semiconductor optical device 1001, and the electrode for connection and the conductive pattern 1079 are connected to each other with solder.

A center position of a pad electrode of the first electrode 1014 and a center position of a pad electrode of the second electrode 1018 are displaced in the extending direction D1. The first transmission line 1084 is connected to the pad electrode of the first electrode 1014 via a first wire 1094. The second transmission line 1088 is connected to the pad electrode of the second electrode 1018 via a second wire 1098. In this case, the first electrode 1014 and the second electrode 1018 are arranged so that the second wire 1098 becomes longer than the first wire 1094. For example, there is assumed a case in which a pair of differential signals are transmitted to the first transmission line 1084 and the second transmission line 1088. In this case, it is preferred that two electric signals forming the pair of differential signals be transmitted to the optical functional layer 6 with the same signal quality. As described above, in the semiconductor optical device 1001, with the plurality of semiconductor interfaces being formed in the first region LR1 and the second region LR2, the spread of the electric field is suppressed, and the capacitance caused by the electrodes is small. However, a distance from the first connection portion 24 to the optical functional layer 6 and a distance from the second connection portion 28 to the optical functional layer 6 are different. The first connection portion 24 is not included in the mesa structure 30, and hence, as compared to the distance from the second connection portion 28 to the optical functional layer 6, the distance from the first connection portion 24 to the optical functional layer 6 is longer. This difference leads to a difference in a frequency characteristic from the first connection portion 24 to the optical functional layer 6 and a frequency characteristic from the second connection portion 28 to the optical functional layer 6. In the tenth example implementation, the difference in frequency characteristic is reduced by adjusting the lengths of the wires. Specifically, the second wire 1098 is intentionally set longer than the first wire 1094 to reduce the difference in frequency characteristic.

The present invention is not limited only to the example implementations described above. The substrate 2 has been described as a semi-insulating semiconductor substrate, but a conductive substrate may be used. However, in a case of using a conductive substrate, a semi-insulating semiconductor layer is arranged between the conductive substrate and the first conductivity type semiconductor layer. Further, the semiconductor optical device is not limited to an electro-absorption modulator, and may be a direct-modulation laser. However, in a case of a semiconductor optical integrated device in which the semiconductor optical device is integrated with a laser section, it is preferred that the semiconductor optical device be an electro-absorption modulator. A case in which the electric signal applied to the semiconductor optical device is a differential signal has been described, but the electric signal may be applied to the semiconductor optical device in single-end drive. Further, the structures including the buried layer have been described. However, the present invention is not limited thereto, and can be applied to the structure without the buried layer.

According to the present invention, in a semiconductor optical device including: a semiconductor multilayer including a first conductivity type semiconductor layer, an optical functional layer, and a second conductivity type semiconductor layer; a first electrode connected to the first conductivity type semiconductor layer; and a second electrode connected to the second conductivity type semiconductor layer, capacitances caused by the electrodes are reduced. A mesa portion of the first conductivity type semiconductor layer, the optical functional layer, and the second conductivity type semiconductor layer form a mesa structure. The first conductivity type semiconductor layer is connected to the first electrode in a first connection portion, and the second conductivity type semiconductor layer is connected to the second electrode in a second connection portion on an upper surface of the mesa structure. The first conductivity type semiconductor layer has a conductive portion which is continuous with the mesa portion included in the mesa structure and includes the first connection portion. A first region is arranged on a side which is continuous with the conductive portion and on which the first electrode is arranged with the conductive portion and a first reference plane being connection planes. With the first region having four or more semiconductor interfaces, the spread of the electric field from the first connection portion is suppressed. Further, it is desired that imaginary lines extending from any position on the first reference plane in a direction parallel to the substrate penetrate the four or more semiconductor interfaces. The number of semiconductor interfaces may be six or more. Each semiconductor interface is formed by an interface between a first high-resistance portion and a second high-resistance portion different from the first high-resistance portion. The first high-resistance portion and the second high-resistance portion may be the same in semiconductor material that serves as a base and different in dopant. The first high-resistance portion may be formed of the same semiconductor as that of the first conductivity type semiconductor layer. It is preferred that the semiconductor interface closest to the first connection portion be arranged at a position overlapping a first bridge electrode of the first electrode when viewed from the top. The second high-resistance portion may be arranged in stripes extending in the extending direction, or may be arranged in islands. When arranged in islands, the islands may be staggered. Further, four or more semiconductor interfaces may be arranged also on a second side surface side, which is a side opposite to a first side surface. When a plurality of modulators are integrated, the semiconductor interfaces have the effect of suppressing the electrical crosstalk among the plurality of modulators. The semiconductor optical device may have a structure of being integrated into a unit with a laser section and a waveguide section. Moreover, the present invention is also applicable to a semiconductor optical apparatus including a sub-mount having mounted thereon a semiconductor optical device. The sub-mount includes a first transmission line and a second transmission line. The first transmission line and the first electrode of the semiconductor optical device are connected to each other by a first wire, and the second transmission line and the second electrode are connected to each other by a second wire. It is desired that the second wire be longer than the first wire.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor optical device, comprising:
a semiconductor multilayer including a first conductivity type semiconductor layer, an optical functional layer, and a second conductivity type semiconductor layer which are grown in the stated order in a stacking direction on a substrate;
a first electrode including a first connection portion connected to the first conductivity type semiconductor layer; and
a second electrode including a second connection portion connected to the second conductivity type semiconductor layer,
wherein a mesa portion of the first conductivity type semiconductor layer, the optical functional layer, and the second conductivity type semiconductor layer form a mesa structure extending in an extending direction,
wherein the first electrode is arranged on one side of the mesa structure in a width direction perpendicular to the stacking direction and the extending direction,
wherein the first conductivity type semiconductor layer includes:
the mesa portion; and
a base portion which is continuous below the mesa portion, extends at least on the one side in the width direction, and is in contact with the first connection portion in a connected portion, and
wherein the semiconductor optical device includes four or more semiconductor interfaces in a first region on the one side in the width direction of the connected portion of the base portion which is in contact with the first connection portion.

2. The semiconductor optical device according to claim 1, wherein each of the four or more semiconductor interfaces is an interface between a first high-resistance portion and a second high-resistance portion which is different from the first high-resistance portion.

3. The semiconductor optical device according to claim 2, wherein, in the first region, any one of imaginary lines extending from a position on a first reference plane, which is a plane located on the width direction side of the connected portion, in a direction parallel to the substrate penetrates the four or more semiconductor interfaces.

4. The semiconductor optical device according to claim 2, wherein the first high-resistance portion and the second high-resistance portion differ from each other in any one of dopant, material that serves as a base, or carrier concentration.

5. The semiconductor optical device according to claim 1,
wherein the first electrode includes a first conducting electrode arranged on the first connection portion, a first pad electrode, and a first bridge electrode arranged between the first conducting electrode and the first pad electrode,
wherein the first bridge electrode is narrower than the first conducting electrode and the first pad electrode in the extending direction,
wherein the base portion includes a conductive portion consisting of a lower portion of the mesa structure and the connected portion, and
wherein, in the width direction, a semiconductor interface closest to the conductive portion among the four or more semiconductor interfaces overlaps the first bridge electrode when viewed from top.

6. The semiconductor optical device according to claim 2,
wherein the semiconductor optical device has a first facet and a second facet which are each a facet in the extending direction, and
wherein the second high-resistance portion reaches from the first facet to the second facet.

7. The semiconductor optical device according to claim 2, wherein the second high-resistance portion is arranged in islands in the first high-resistance portion.

8. The semiconductor optical device according to claim 3,
wherein the second high-resistance portion is arranged in a staggered manner in the first high-resistance portion, and
wherein the imaginary lines parallel to the width direction among the imaginary lines all penetrate the four or more semiconductor interfaces.

9. The semiconductor optical device according to claim 2, wherein, in the first region, the first high-resistance portion is arranged in islands in the second high-resistance portion.

10. The semiconductor optical device according to claim 1, wherein the base portion includes four or more semiconductor interfaces in a second region on another side in the width direction of the connected portion which is in contact with the first connection portion.

11. The semiconductor optical device according to claim 10, wherein, in the second region, any one of imaginary lines extending from a position on a second reference plane, which is a plane located on the width direction side of the connected portion, in a direction parallel to the substrate penetrates the four or more semiconductor interfaces arranged in the second region.

12. The semiconductor optical device according to claim 10,
wherein the second electrode includes a second conducting electrode arranged on the second connection portion, a second pad electrode, and a second bridge electrode arranged between the second conducting electrode and the second pad electrode,
wherein the second bridge electrode is narrower than the second conducting electrode and the second pad electrode in the extending direction,
wherein the base portion includes a conductive portion consisting of a lower portion of the mesa structure and the connected portion, and
wherein, in the width direction, a semiconductor interface closest to the conductive portion among the four or more semiconductor interfaces overlaps the second bridge electrode when viewed from top.

13. The semiconductor optical device according to claim 5,
wherein the semiconductor optical device has a first facet and a second facet which are each a facet in the extending direction, and
wherein, in the extending direction, the second high-resistance portion is arranged between the conductive portion and one of the first facet or the second facet.

14. The semiconductor optical device according to claim 13, wherein the second high-resistance portion is arranged so as to avoid the mesa structure when viewed from top.

15. The semiconductor optical device according to claim 1,
wherein the first electrode includes a first pad electrode,
wherein the second electrode includes a second pad electrode, and
wherein the first pad electrode and the second pad electrode overlap the first region when viewed from top.

16. A semiconductor optical integrated device, comprising a plurality of the semiconductor optical devices of claim 1 arranged on the substrate in the width direction.

17. The semiconductor optical device according to claim 1, wherein, in the extending direction, both ends of the second connection portion are inside both ends of the first connection portion.

18. The semiconductor optical device according to claim 1, further comprising:
a modulation section including the optical functional layer;
a laser section; and
a waveguide section arranged between the modulation section and the laser section.

19. A semiconductor optical apparatus, comprising:
the semiconductor optical device of claim 1; and
a sub-mount on which the semiconductor optical device is mounted.

20. The semiconductor optical apparatus according to claim 19,
wherein the sub-mount includes a first transmission line and a second transmission line,
wherein the semiconductor optical apparatus further comprises:
a first wire connecting the first transmission line and the first electrode to each other; and
a second wire connecting the second transmission line and the second electrode to each other, and
wherein the second wire is longer than the first wire.
